(19) United States
(12) Patent Application Publication
(10) Pub. No.: US 2022/0302319 A1
(43) Pub. Date: Sep. 22, 2022

(54) THIN-FILM STRUCTURE, SEMICONDUCTOR ELEMENT INCLUDING THE THIN-FILM STRUCTURE, AND METHOD OF MANUFACTURING THE THIN-FILM STRUCTURE

(71) Applicants: Samsung Electronics Co., Ltd., Suwon-si (KR); UNIST (ULSAN NATIONAL INSTITUTE OF SCIENCE AND TECHNOLOGY), Ulsan (KR)

(72) Inventors: Changseok LEE, Gwacheon-si (KR); Soonyong KWON, Ulsan (KR); Junghwa KIM, Ulsan (KR); Seungwoo SON, Ulsan (KR); Seunguk SONG, Ulsan (KR); Hyeonjin SHIN, Suwon-si (KR); Zonghoon LEE, Ulsan (KR); Yeonchoo CHO, Seongnam-si (KR)

(73) Assignees: Samsung Electronics Co., Ltd., Suwon-si (KR); UNIST (ULSAN NATIONAL INSTITUTE OF SCIENCE AND TECHNOLOGY), Ulsan (KR)

(21) Appl. No.: 17/495,457

(22) Filed: Oct. 6, 2021

(30) Foreign Application Priority Data
Mar. 18, 2021 (KR) 10-2021-0035348

(51) Int. Cl. H01L 29/786; H01L 29/16; H01L 29/66; H01L 29/06

(52) U.S. Cl. CPC H01L 29/78681; H01L 29/1606; H01L 29/66045; H01L 29/0665; H01L 29/78696; B82Y 10/00

(57) ABSTRACT

Provided is a thin-film structure including a substrate, a nanocrystalline graphene layer provided on the substrate, and a two-dimensional material layer provided on the nanocrystalline graphene layer. The nucleation density of the two-dimensional material layer is 10⁹ ea/cm² or more according to the nanocrystalline graphene layer, and accordingly, a two-dimensional material layer having an improved uniformity may be formed and a time duration for forming the two-dimensional material layer may be greatly decreased.

### CROSS-REFERENCE TO RELATED APPLICATION

This application is based on and claims priority under 35 U.S.C. § 119 to Korean Patent Application No. 10-2021-0035348, filed on Mar. 18, 2021, in the Korean Intellectual Property Office, the disclosure of which is incorporated by reference herein in its entirety.

### BACKGROUND

### 1. Field

The present disclosure relates to thin-film structures, semiconductor elements including the thin-film structures, and methods of manufacturing the thin-film structures.

### 2. Description of the Related Art

Graphene is a representative two-dimensional material with excellent mechanical, thermal, and electrical properties. However, graphene has a fundamental limitation in its application to electronic elements and optical elements due to the absence of an energy bandgap.

As a two-dimensional material that can replace graphene, transition metal dichalcogenide (TMD) has been recently proposed. TMD is generally represented by a chemical formula of MX₂. In this case, M is a transition metal element such as Mo, W, and Ti, and X is a chalcogen element such as S, Se, and Te.

In principle, TMD only interacts in two dimensions with its constituent atoms. Accordingly, the transport of carriers in TMD exhibits a trajectory transport pattern completely different from that of a conventional thin film or bulk, and thus, high mobility, high speed, and low power characteristics may be realized. In addition, TMD is flexible and transparent because the thickness thereof is very thin as much as thickness of a few atomic layers, and exhibits various properties such as electric properties of semiconductors and conductors.

In particular, TMD with semiconductor properties has an appropriate band gap and exhibits electron mobility of several hundred cm²/V·s. Therefore, TMD is suitable for the application of semiconductor elements such as transistors, and has great potential for flexible transistor elements in the future.

A method of manufacturing a TMD nano thin film has been actively studied in recent years. In order to apply the TMD nano thin film as the above elements, a method of uniformly and continuously synthesizing a thin film having a large area has been studied.

### SUMMARY

Provided are thin-film structures having structures in which the nucleation density of a two-dimensional material layer is increased, semiconductor elements including the thin-film structures, and method of manufacturing the thin-film structures.

Additional aspects will be set forth in part in the description which follows and, in part, will be apparent from the description, or may be learned by practice of the presented embodiments of the disclosure.

According to an embodiment, a thin-film structure includes a substrate, a nanocrystalline graphene layer on the substrate, and a two-dimensional material layer on the nanocrystalline graphene layer. A nucleation density of the two-dimensional material layer may be 10⁹ ea/cm² or more according to the nanocrystalline graphene layer.

In some embodiments, a grain size of the nanocrystalline graphene layer may be about 1 nm to about 1,000 nm.

In some embodiments, the two-dimensional material layer may include transition metal dichalcogenide (TMD).

In some embodiments, the TMD may include a composition represented by a chemical formula MX₂, wherein M is a transition metal element and X is a chalcogen element.

In some embodiments, the two-dimensional material layer may include at least one of h-BN, a-BN, MXene, Silicene, Stanene, Tellurene, Borophene, Antimonene, Bi₂Se₃, and Bi₂O₂Se.

In some embodiments, the substrate may include at least one of silicon (Si), silicon dioxide (SiO₂), aluminum oxide (Al₂O₃), quartz, germanium (Ge), gallium nitride (GaN), aluminum nitride (AlN), gallium phosphorus. (GaP), indium phosphide (InP), gallium arsenide (GaAs), silicon carbide (SiC), lithium aluminum oxide (LiAlO₃), magnesium oxide (MgO), polyethylene naphthalate (PEN), and polyethylene terephthalate (PET).

According to an embodiment, a semiconductor element includes a thin-film structure including a nanocrystalline graphene layer, and a two-dimensional material layer on the nanocrystalline graphene layer. A nucleation density of the two-dimensional material layer may be 10⁹ ea/cm² or more according to the nanocrystalline graphene layer.

In some embodiments, a grain size of the nanocrystalline graphene layer may be about 1 nm to about 1,000 nm.

In some embodiments, the two-dimensional material layer may include transition metal dichalcogenide (TMD).

In some embodiments, the TMD may include a composition represented by a chemical formula MX₂, wherein M is a transition metal element and X is a chalcogen element.

In some embodiments, the semiconductor element may further include a gate electrode spaced apart from the two-dimensional material layer, and a gate insulating layer between the two-dimensional material layer and the gate electrode.

In some embodiments, the gate insulating layer may include at least one of silicon oxide, silicon nitride, aluminum oxide (Al₂O₃), hafnium oxide (HfO₂), zirconium oxide (ZrO₂), silicon oxynitride (SiON), and a high-k material.

In some embodiments, the semiconductor element may further include a source electrode and a drain electrode electrically connected to both ends of the thin-film structure, respectively.

In some embodiments, each of the source electrode and the drain electrode may include at least one of gold (Au), silver (Ag), aluminum (Al), copper (Cu), tungsten (W), cobalt (Co), nickel (Ni), titanium (Ti), tantalum (Ta), titanium nitride (TiN), titanium aluminide (TiAl), titanium aluminide nitride (TiAlN), and tantalum nitride (TaN).

In some embodiments, the semiconductor element may be an optoelectronic device.

In some embodiments, the semiconductor element may further include a conductive layer on the two-dimensional material layer.

According to an embodiment, a method of manufacturing a thin-film structure includes forming a nanocrystalline graphene layer on a substrate in a reaction chamber, and forming a two-dimensional material layer on the nanocrystalline graphene layer. A nucleation density of the two-dimensional material layer may be 10⁹ ea/cm² or more according to the nanocrystalline graphene layer.

In some embodiments, the forming the two-dimensional material layer may include supplying two or more types of precursors of transition metal dichalcogenide (TMD) to the reaction chamber to form the two-dimensional material layer.

In some embodiments, a time for supplying the precursors to the reaction chamber may be about 5 minutes or more and about 30 minutes or less.

In some embodiments, the forming the two-dimensional material layer may be performed by using a chemical vapor deposition (CVD) process, a physical vapor deposition (PVD) process, an atomic layer deposition (ALD) process, or a combination of at least two thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 schematically illustrates an example structure of a thin-film structure according to an embodiment;

FIG. 2 is a flowchart illustrating a method of manufacturing a thin-film structure, according to an embodiment;

FIG. 3 schematically illustrates a state in which a nanocrystalline graphene layer is formed on a substrate according to a method of manufacturing a thin-film structure according to an embodiment;

FIG. 4 illustrates a state in which nuclei of a two-dimensional material layer are formed on a nanocrystalline graphene layer according to a method of manufacturing a thin-film structure according to an embodiment;

FIG. 5 is a photograph illustrating the nucleation density of a two-dimensional material layer formed on a nanocrystalline graphene layer according to a method of manufacturing a thin-film structure according to an embodiment;

FIG. 6 schematically illustrates an example structure of a thin-film structure manufactured according to a method of manufacturing a thin-film structure according to an embodiment;

FIG. 7 schematically illustrates an example structure of a semiconductor element according to an embodiment; and

FIG. 8 schematically illustrates an example structure of a semiconductor element according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

In the drawings, the size or thickness of each component may be exaggerated for clarity and convenience.

Hereinafter, what is described as “on” or “over” may include not only that which is directly above in contact, but also that which is above in a non-contact manner. As used herein, the singular forms “a”, “an” and “the” are intended to include the plural forms as well, unless the context clearly indicates otherwise. When a part is said to “include” a component, this means that other components may be further included instead of excluding other components, unless otherwise stated.

The use of the term “above-described” and similar indication terms may correspond to both singular and plural.

Although the terms “first”, “second”, etc., may be used herein to describe various elements, components, regions, and/or layers, these elements, components, regions, and/or layers should not be limited by these terms. These terms are used only to distinguish one component from another, not for purposes of limitation.

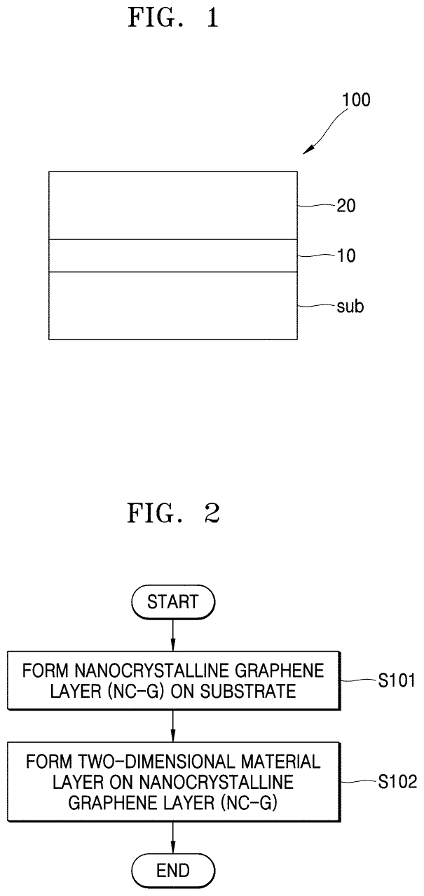

FIG. 1 schematically illustrates an example structure of a thin-film structure 100 according to an embodiment.

Referring to FIG. 1, the thin-film structure 100 may include a substrate sub, a nanocrystalline graphene layer 10 provided on the substrate sub, and a two-dimensional material layer 20 provided on the nanocrystalline graphene layer 10.

When the two-dimensional material layer 20 is directly formed on a substrate sub including silicon, etc., not the nanocrystalline graphene layer 10, it may be difficult to control the nucleation density and uniformity of the two-dimensional material layer 20. For example, in a process of forming the two-dimensional material layer 20 on the substrate sub provided in a reaction chamber, a precursor of a material included in the two-dimensional material layer 20 may be used. In this case, crystal nuclei of the two-dimensional material layer 20 may be formed on the substrate sub while the precursor is deposited on the substrate sub. The nucleation density of the crystal nuclei of the two-dimensional material layer 20 formed on the substrate sub may vary depending on the state of the substrate sub. When the nucleation density is not high enough, the uniformity of the two-dimensional material layer 20 decreases, and the time required to form the two-dimensional material layer 20 increases. In order to sufficiently increase the nucleation density of the two-dimensional material layer 20, it is necessary to select a substrate sub having an appropriate grain size, and accordingly, there may be limitations in selecting the substrate sub on which the two-dimensional material layer 20 is formed.

In the thin film structure 100 according to the embodiment, the two-dimensional material layer 20 is not directly formed on the substrate sub, but is formed on the nanocrystalline graphene layer 10, and thus, the uniformity of the two-dimensional material layer 20 may be improved.

The substrate sub may include various types of materials. For example, the substrate sub may include at least one of silicon (Si), silicon dioxide (SiO₂), aluminum oxide (Al₂O₃), quartz, germanium (Ge), gallium nitride (GaN), aluminum nitride (AlN), gallium phosphorus. (GaP), indium phosphide (InP), gallium arsenide (GaAs), silicon carbide (SiC), lithium aluminum oxide (LiAlO₃), magnesium oxide (MgO), polyethylene naphthalate (PEN), polyethylene terephthalate (PET). However, the disclosure is not limited thereto, and the substrate sub may include an appropriate material as necessary. For example, the substrate sub may include glass, graphene, metal foil, sapphire, molybdenum disulfide (MoS₂), or the like.

The nanocrystalline graphene layer 10 is a layer inserted between the substrate sub and the two-dimensional material layer 20, and may be a layer that enables the two-dimensional material layer 20 to be more efficiently formed on the substrate sub. The nanocrystalline graphene layer 10 may allow the nucleation density of the two-dimensional material layer to be 10⁹ ea/cm² or more. For example, the grain size of the nanocrystalline graphene layer 10 may be about 1 nm to about 1000 nm. In this way, the nanocrystalline graphene layer 10 may have a sufficiently small grain size such that the nucleation density of the two-dimensional material layer 20 may be 10⁹ ea/cm² or more in a process in which the precursor of the two-dimensional material layer 20 is deposited on the nanocrystalline graphene layer 10. For example, the nucleation density of the two-dimensional material layer 20 may be about 1.7×10⁹ ea/cm². However, the disclosure is not limited thereto, and the nucleation density of the two-dimensional material layer 20 may be greater than about 1.7×10⁹ ea/cm².

The two-dimensional material layer 20 may include transition metal dichalcogenide (TMD). The TMD may include a composition represented by a chemical formula MX₂. In this case, M is a transition metal element, and X is a chalcogen element. For example, the transition metal element may be selected from among molybdenum (Mo), tungsten (W), palladium (Pd), platinum (Pt), titanium (Ti), zirconium (Zr), hafnium (Hf), vanadium (V), niobium (Nb), tantalum (Ta), techthenium (Tc), rhenium (Re), cobalt (Co), rhodium (Rh), iridium (Ir), nickel (Ni), zinc (Zn), and tin (Sn). In addition, X may be selected from among sulfur (S), selenium (Se), and tellurium (Te). For example, the TMD may include at least one of MoS₂, MoSe₂, W₅₂, WSe₂, WTe₂, MoTe₂, ZrS₂, ZrSe₂, GaSe, GaTe₂, HfS₂, HfSe₂, SnSe, PtSe₂, PdSe₂, PdTe₂, ReSe₂, VS₂, VSe₂, NbSe₂, FeSe₂, and FeTe₂.

However, the disclosure is not limited thereto, and the two-dimensional material layer 20 may include various two-dimensional materials in addition to the TMD. For example, the two-dimensional material layer 20 may include at least one of h-BN, a-BN, MXene, Silicene, Stanene, Tellurene, Borophene, Antimonene, Bi₂Se₃, and Bi₂O₂Se.

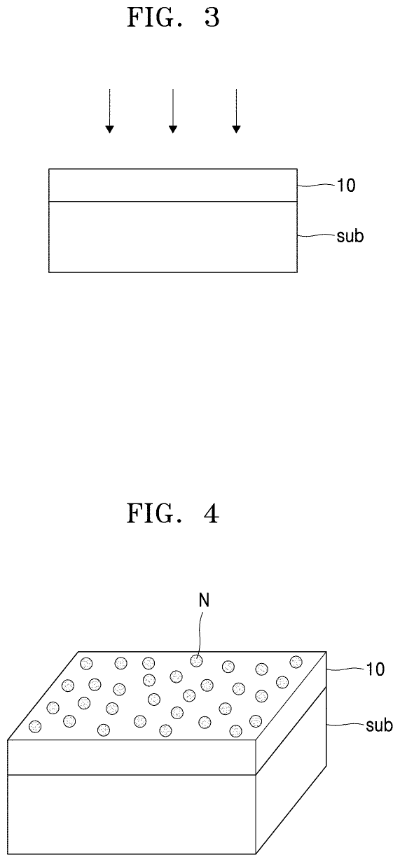

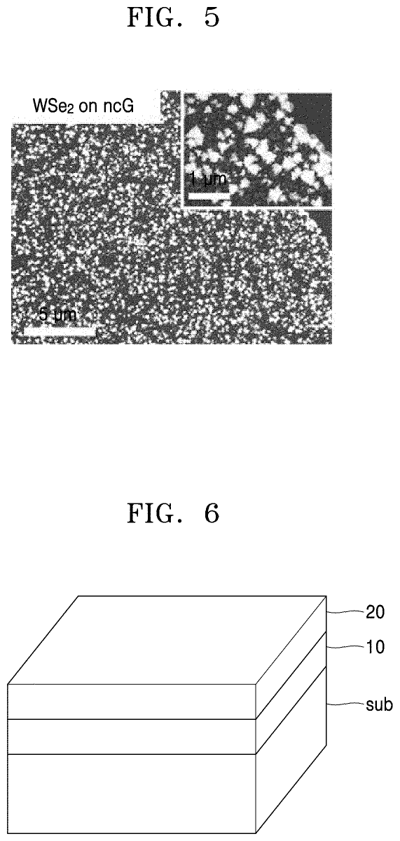

FIG. 2 is a flowchart illustrating a method of manufacturing a thin-film structure, according to an embodiment. FIG. 3 schematically illustrates a state in which a nanocrystalline graphene layer 10 is formed on a substrate sub according to the method of manufacturing a thin-film structure according to the embodiment. FIG. 4 illustrates a state in which nuclei N of a two-dimensional material layer 20 are formed on the nanocrystalline graphene layer 10 according to the method of manufacturing a thin-film structure according to the embodiment. FIG. 5 is a photograph illustrating the nucleation density of the two-dimensional material layer 20 formed on the nanocrystalline graphene layer 10 according to the method of manufacturing a thin-film structure according to the embodiment. FIG. 6 schematically illustrates an example structure of a thin-film structure 100 manufactured according to the method of manufacturing a thin-film structure according to the embodiment.

Referring to FIG. 2, the method of manufacturing a thin-film structure according to an embodiment may include forming a nanocrystalline graphene layer 10 on a substrate sub provided in a reaction chamber (operation S101), and forming a two-dimensional material layer 20 on the nanocrystalline graphene layer 10 (operation S102).

As shown in FIG. 3, the nanocrystalline graphene layer 10 may be formed on the substrate sub. In operation S101 of forming the nanocrystalline graphene layer 10 on the substrate sub, a chemical vapor deposition (CVD) process, a physical vapor deposition (PVD) process, an atomic layer deposition (ALD) process, or a combination of at least two thereof may be used to form the nanocrystalline graphene layer 10 on the substrate sub provided in the reaction chamber.

Examples of the CVD process include a plasma enhanced chemical vapor deposition (PECVD) process and a metal organic chemical vapor deposition (MOCVD) process. Examples of the PVD process include a vacuum deposition process, a sputtering process, and an ion plating process. However, the disclosure is not limited thereto, and a method of forming the nanocrystalline graphene layer 10 on the substrate may be various. In this case, the nanocrystalline graphene layer 10 may have a grain size of about 1 nm to about 1000 nm.

As shown in FIG. 4, nuclei N for forming a two-dimensional material layer 20 on the nanocrystalline graphene layer 10 may be generated. By further growing the nuclei N, as shown in FIG. 6, a two-dimensional material layer 20 may be formed on the nanocrystalline graphene layer 10. A CVD process, a PVD process, an ALD process, or a combination of at least two thereof may be used to form the two-dimensional material layer 20 on the nanocrystalline graphene layer 10. However, the disclosure is not limited thereto, and a method of forming the two-dimensional material layer 20 on the nanocrystalline graphene layer 10 may be variously modified.

For example, in operation S102 of forming a two-dimensional material layer 20 on the nanocrystalline graphene layer 10, two or more types of precursors of TMD may be supplied to the reaction chamber under a certain temperature and a certain pressure to form the two-dimensional material layer 20. The two or more types of precursors may include a precursor including a transition metal element and a precursor including a chalcogen element. Precursors supplied into the reaction chamber may be deposited on the nanocrystalline graphene layer 10 to thereby generate nuclei N for forming the two-dimensional material layer 20. As shown in FIG. 5, the nucleation density of the two-dimensional material layer 20 formed on the nanocrystalline graphene layer 10 having a grain size of about 1 nm to about 1000 nm may be about 10⁹ ea/cm². As such, the uniformity of the two-dimensional material layer 20 may increase according to a large nucleation density of 10⁹ ea/cm² or more. In addition, a time for supplying precursors to the reaction chamber to form the two-dimensional material layer 20 may be greatly decreased. For example, the time for supplying precursors to the reaction chamber may be 5 minutes or more and 30 minutes or less.

For example, the precursor including the transition metal element may include at least one element selected from among Ti, Zr, Hf, V, Nb, Ta, Mo, W, Tc, Re, Co, Rh, Ir, Ni, Pd, Pt, Zn, and Sn. For example, the precursor including the transition metal element may include a metal oxide, a metal halide, a metal carbonyl compound, or a combination thereof, which contains the element described above.

For example, the precursor including the chalcogen element may include at least one element selected from among S, Se, and Te. The precursor including the chalcogen element may include at least one selected from among sulfide (S), hydrogen sulfide (H₂S), diethyl sulfide, dimethyl disulfide, ethyl methyl sulfide, (Et₃Si)₂S, hydrogen selenide (H₂Se), diethyl selenide, dimethyl diselenide, ethyl methyl selenide, (Et₃Si)₂Se, hydrogen telenium (H₂Te), dimethyl telluride, diethyl telluride, ethyl methyl telluride, and (Et₃Si)₂Te.

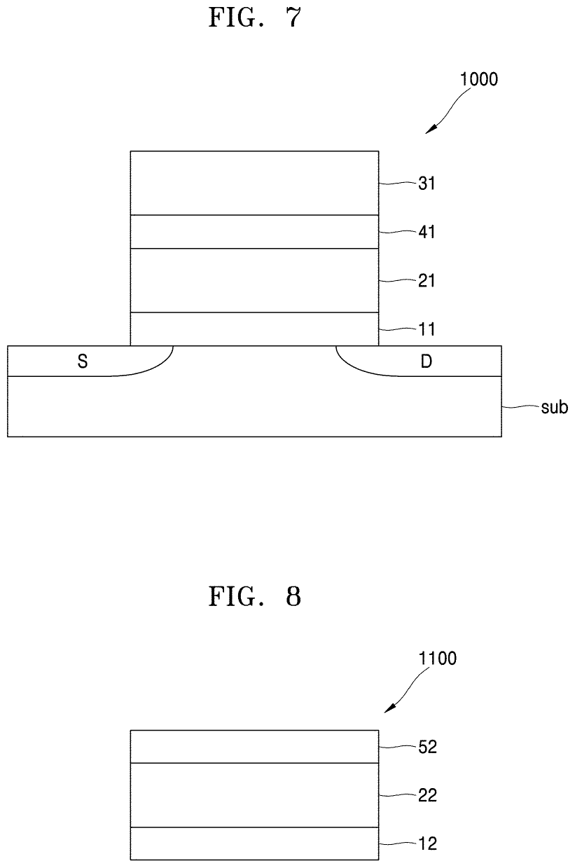

FIG. 7 schematically illustrates an example structure of a semiconductor element 1000 according to an embodiment. A nanocrystalline graphene layer 11 and a two-dimensional material layer 21 may be substantially the same as the nanocrystalline graphene layer 10 and the two-dimensional material layer 20 of FIG. 1, respectively. Regarding FIG. 7, descriptions that are the same as those with respect to FIG. 6 are omitted.

Referring to FIG. 7, the semiconductor element 1000 may include a transistor structure. The semiconductor element 1000 having a transistor structure may include a thin-film structure including a nanocrystalline graphene layer 11 and a two-dimensional material layer 21 provided on the nanocrystalline graphene layer 11. In addition, the semiconductor element 1000 having a transistor structure may further include a gate electrode 31 spaced apart from the two-dimensional material layer 21, a gate insulating layer 41 provided between the two-dimensional material layer 21 and the gate electrode 31, and a source electrode S and a drain electrode D electrically connected to both ends of the thin-film structure, respectively. In this case, the thin-film structure including the nanocrystalline graphene layer 11 and the two-dimensional material layer 21 may function as a channel layer of the semiconductor device 1000. Although, in FIG. 7, the two-dimensional material layer 21 is provided on the nanocrystalline graphene layer 11, the disclosure is not limited thereto and the nanocrystalline graphene layer 11 may be omitted.

The gate electrode 31 may include doped polysilicon having a uniform or non-uniform doping concentration. However, the disclosure is not limited thereto, and the gate electrode 31 may include at least one of aluminum (Al), copper (Cu), W, Ti, Co, Ni, Ta, titanium nitride (TiN), titanium aluminide (TiAl), titanium nitride aluminide (TiAlN), and tantalum nitride (TaN). The gate electrode 31 may be formed through a CVD process, a PVD process, an ALD process, or the like.

The gate insulating layer 41 may insulate the two-dimensional material layer 21 from the gate electrode 31. For example, the gate insulating layer 41 may include silicon oxide, silicon nitride, aluminum oxide (Al₂O₃), hafnium oxide (HfO₂), zirconium oxide (ZrO₂), silicon oxynitride (SiON), or a high-k material. The high-k material may include at least one element selected from among lithium (Li), beryllium (Be), magnesium (Mg), calcium (Ca), strontium (Sr), scandium (Sc), yttrium (Y), zirconium (Zr), hafnium (Hf), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), tolium (Tm), ytterbium (Yb), lutetium (Lu), and the like. The gate insulating layer 41 may include a single layer or may include a plurality of layers. The gate insulating layer 41 may be formed through a CVD process, a PVD process, an ALD process, or the like.

The source electrode S and the drain electrode D may each include at least one of gold (Au), silver (Ag), aluminum (Al), copper (Cu), tungsten (W), cobalt (Co), nickel (Ni), titanium (Ti), tantalum (Ta), titanium nitride (TiN), titanium aluminide (TiAl), titanium aluminide nitride (TiAlN), and tantalum nitride (TaN). The source electrode S and the drain electrode D may be formed to contact both ends of the nanocrystalline graphene layer 11, respectively. However, the disclosure is not limited thereto, and the source electrode S and the drain electrode D may be formed to contact both ends of the two-dimensional material layer 21, respectively.

FIG. 8 schematically illustrates an example structure of a semiconductor element 1100 according to another embodiment. A nanocrystalline graphene layer 12 and a two-dimensional material layer 22 may be substantially the same as the nanocrystalline graphene layer 10 and the two-dimensional material layer 20 of FIG. 1, respectively. Regarding FIG. 8, descriptions that are the same as those with respect to FIG. 6 are omitted.

Referring to FIG. 8, the semiconductor element 1100 may be an optoelectronic device, and may include a thin-film structure including a nanocrystalline graphene layer 12 and a two-dimensional material layer 22 provided on the nanocrystalline graphene layer 12. In addition, the semiconductor element 1100, which is an optoelectronic device, may further include a conductive layer 52 provided on the two-dimensional material layer 22. The conductive layer 52 may include nanocrystalline graphene or metal. In this case, the semiconductor element 1100 may function as an MSM diode having a metal/semiconductor/metal structure.

According to various embodiments of the disclosure, a thin-film structure having a structure in which the nucleation density of a two-dimensional material layer is increased, a semiconductor element including the thin-film structure, and a method of manufacturing the thin-film structure may be provided.

According to various embodiments of the disclosure, a two-dimensional material layer may be formed on a nanocrystalline graphene layer. In a process of forming a two-dimensional material layer on the nanocrystalline graphene layer, the nucleation density of the two-dimensional material layer may be 10⁹ ea/cm² or more, and accordingly, the uniformity of the two-dimensional material layer may increase and a manufacturing time may be greatly decreased.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A thin-film structure comprising:
a substrate;
a nanocrystalline graphene layer on the substrate; and
a two-dimensional material layer on the nanocrystalline graphene layer,
wherein a nucleation density of the two-dimensional material layer is 10⁹ ea/cm² or more according to the nanocrystalline graphene layer.

2. The thin-film structure of claim 1,
wherein a grain size of the nanocrystalline graphene layer is about 1 nm to about 1,000 nm.

3. The thin-film structure of claim 1,
wherein the two-dimensional material layer includes transition metal dichalcogenide (TMD).

4. The thin-film structure of claim 3,
wherein the TMD includes a composition represented by a chemical formula MX₂, wherein M is a transition metal element and X is a chalcogen element.

5. The thin-film structure of claim 1,
wherein the two-dimensional material layer includes at least one of h-BN, a-BN, MXene, Silicene, Stanene, Tellurene, Borophene, Antimonene, Bi₂Se₃, and Bi₂O₂Se.

6. The thin-film structure of claim 1,
wherein the substrate includes at least one of silicon (Si), silicon dioxide (SiO₂), aluminum oxide (Al₂O₃), quartz, germanium (Ge), gallium nitride (GaN), aluminum nitride (AlN), gallium phosphorus. (GaP), indium phosphide (InP), gallium arsenide (GaAs), silicon carbide (SiC), lithium aluminum oxide (LiAlO₃), magnesium oxide (MgO), polyethylene naphthalate (PEN), and polyethylene terephthalate (PET).

7. A semiconductor element comprising:
a thin-film structure including a nanocrystalline graphene layer and a two-dimensional material layer on the nanocrystalline graphene layer,
wherein a nucleation density of the two-dimensional material layer is 10⁹ ea/cm² or more according to the nanocrystalline graphene layer.

8. The semiconductor element of claim 7,
wherein a grain size of the nanocrystalline graphene layer is about 1 nm to about 1,000 nm.

9. The semiconductor element of claim 7,
wherein the two-dimensional material layer includes transition metal dichalcogenide (TMD).

10. The semiconductor element of claim 9,
wherein the TMD includes a composition represented by a chemical formula MX₂, wherein M is a transition metal element and X is a chalcogen element.

11. The semiconductor element of claim 7, further comprising:
a gate electrode spaced apart from the two-dimensional material layer; and
a gate insulating layer between the two-dimensional material layer and the gate electrode.

12. The semiconductor element of claim 11,
wherein the gate insulating layer includes at least one of silicon oxide, silicon nitride, aluminum oxide (Al₂O₃), hafnium oxide (HfO₂), zirconium oxide (ZrO₂), silicon oxynitride (SiON), and a high-k material.

13. The semiconductor element of claim 11, further comprising:
a source electrode and a drain electrode electrically connected to both ends of the thin-film structure, respectively.

14. The semiconductor element of claim 13,
wherein each of the source electrode and the drain electrode includes at least one of gold (Au), silver (Ag), aluminum (Al), copper (Cu), tungsten (W), cobalt (Co), nickel (Ni), titanium (Ti), tantalum (Ta), titanium nitride (TiN), titanium aluminide (TiAl), titanium aluminide nitride (TiAlN), and tantalum nitride (TaN).

15. The semiconductor element of claim 7,
wherein the semiconductor element is an optoelectronic element.

16. The semiconductor element of claim 7, further comprising:
a conductive layer on the two-dimensional material layer.

17. A method of manufacturing a thin-film structure, the method comprising:
forming a nanocrystalline graphene layer on a substrate in a reaction chamber; and
forming a two-dimensional material layer on the nanocrystalline graphene layer,
wherein a nucleation density of the two-dimensional material layer is 10⁹ ea/cm² or more according to the nanocrystalline graphene layer.

18. The method of claim 17,
wherein the forming the two-dimensional material layer includes supplying two or more types of precursors of transition metal dichalcogenide (TMD) to the reaction chamber to form the two-dimensional material layer.

19. The method of claim 18,
wherein a time for supplying the precursors to the reaction chamber is about 5 minutes or more and about 30 minutes or less.

20. The method of claim 17,
wherein the forming the two-dimensional material layer is performed by using a chemical vapor deposition (CVD) process, a physical vapor deposition (PVD) process, an atomic layer deposition (ALD) process, or a combination of at least two thereof.
